(19) United States
(12) Patent Application Publication
(10) Pub. No.: US 2015/0364352 A1
(43) Pub. Date: Dec. 17, 2015

(54) Wafer Loading and Unloading

(71) Applicant: VEECO INSTRUMENTS INC., Plainview, NY (US)

(72) Inventor: Mandar Deshpande, Bridgewater, NJ (US)

(21) Appl. No.: 14/301,459

(22) Filed: Jun. 11, 2014

(51) Int. Cl. H01L 21/677; H01L 21/683; H01L 21/687; H01L 21/68

(52) U.S. Cl. CPC H01L 21/67712; H01L 21/67709; H01L 21/67706; H01L 21/68; H01L 21/6831; H01L 21/6838; H01L 21/687

(57) ABSTRACT

A robotic handling system loads and unloads wafers (e.g., silicon wafers) and their carriers into and out of an interlock chamber of a loadlock system. The wafer handling system includes an end effector that handles both the wafer and the carrier by their bottom surfaces, avoiding contact with the top surface of the wafer. From the interlock chamber, wafers, seated on the carrier, are moved into a processing chamber under vacuum conditions. Processed wafers, seated on the carrier, are moved from the processing chamber back into the interlock chamber and removed from the interlock chamber by the robotic handling system under atmospheric conditions.

### BACKGROUND

Users of wafer handling and processing equipment would like the systems to be fairly simple and inexpensive, occupy a minimal amount of floor space, be able to operate with minimal contamination (e.g., particle) creation, and have a short transfer time in order to minimize cycle time. Various systems are known for handling wafers within the semiconductor processing system, including robotic systems that maneuver the wafer as needed. Improvements, however, are needed.

### SUMMARY

The described technology is directed to a wafer loading and unloading system that includes a robotic end effector to move a wafer and a wafer carrier into and out from a loadlock chamber. Example implementations of the described technology provide wafer processing systems that include a robotic handling system for loading and unloading wafers (e.g., silicon wafers) and their carriers into and out of a loadlock chamber. The wafer handling system includes a robot with two end effectors that handle the wafer and the carrier by their bottom surfaces, avoiding contact with the top surface of the wafer. From the loadlock chamber, wafers, seated on the carrier, are moved into a processing chamber under vacuum conditions. Processed wafers, seated on the carrier, are moved from the processing chamber back into the loadlock chamber and removed from the loadlock chamber by the robotic handling system under atmospheric conditions.

These and various other features and advantages will be apparent from a reading of the following detailed description.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Other implementations are also described and recited herein.

### BRIEF DESCRIPTION OF THE DRAWING

FIG. 1 is a schematic diagram of a wafer processing system.

FIG. 2 is a schematic composite side view and cross-sectional view of a loadlock chamber having a wafer and carrier therein.

FIGS. 3A through 3J schematically illustrate, step-wise, an example method of loading a carrier and a wafer into a loadlock chamber.

FIGS. 4A through 4J schematically illustrate, step-wise, an example method of unloading a wafer and a carrier from a loadlock chamber.

FIG. 5 is a flow chart outlining a method of lifting a wafer.

FIG. 6 is a flow chart outlining a method of inputting a carrier into a loadlock chamber.

### DETAILED DESCRIPTION

The present description is directed to wafer processing systems that include a robotic handling system for loading and unloading wafers (e.g., silicon wafers) and their carriers into and out of a loadlock chamber. The wafer handling system includes an end effector that handles both the wafer and the carrier by their bottom surfaces, avoiding contact with the top surface of the wafer. From the loadlock chamber, wafers, seated on the carrier, are moved into a processing chamber under vacuum conditions. Processed wafers, seated on the carrier, are moved from the processing chamber back into the loadlock chamber and removed from the loadlock chamber by the robotic handling system under atmospheric conditions. Present within the loadlock chamber is a vertically-oriented lifting head that moves (e.g., lifts and lowers) the wafer into and out from the carrier.

Integrated circuits are formed by many semiconductor devices, such as transistors and diodes, formed on a thin slice of semiconductor material, known as a wafer. Some of the processes used in the manufacturing of semiconductor devices on the wafer involve positioning the wafer in various processing chambers where various layers and features are built-up, patterned, removed, etc. to form the semiconductor features on the wafer. In order to form such integrated circuits on a wafer, the wafer is loaded into the processing chamber. However, since the wafer is extremely brittle and vulnerable to particulate contamination, great care must be taken so as to avoid physically damaging the wafer while it is being transported. To avoid damaging the wafer during the transport process, various wafer pickup devices have been developed.

The use of fully automated wafer handling equipment using robots is common in high volume semiconductor manufacturing. In this type of handling equipment, robots move wafers from cassettes known as FOUPS or SMIFS maintained at atmospheric pressure into process chambers, which in some implementations are under vacuum. Because of this, a sophisticated architecture is needed, having an atmospheric handling side with its dedicated robots and a vacuum handling side with its dedicated robots; various vacuum isolation valves and chambers are also needed.

Unlike the standard semiconductor industry this sophisticated level of automation has been more complicated and not cost effective for certain types of process equipment such as compound semiconductor MOCVD systems. The complication is introduced because unlike standard semiconductor systems that only transfer wafers such these systems need the wafer to be transferred along with a wafer carrier or holder into the process chamber. This necessitates an extra step in the automation process of loading and unloading the wafer onto this wafer carrier or holder. Achieving this loading or unloading may require additional robots and fixtures driving the cost of the equipment higher. A simpler cost effective solution of achieving this step can allow the use of standard automation equipment for this type of process equipment much more cost effectively.

The present disclosure provides a handling system for wafers and for the carriers that support the wafer during processing.

In the following description, reference is made to the accompanying drawing that forms a part hereof and in which are shown by way of illustration at least one specific embodiment. The following description provides additional specific embodiments. It is to be understood that other embodiments are contemplated and may be made without departing from the scope or spirit of the present invention. The following detailed description, therefore, is not to be taken in a limiting sense. While the present invention is not so limited, an appreciation of various aspects of the invention will be gained through a discussion of the examples provided below.

As used herein, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

Spatially related terms, including but not limited to, “lower”, “upper”, “beneath”, “below”, “above”, “on top”, etc., if used herein, are utilized for ease of description to describe spatial relationships of an element(s) to another. Such spatially related terms encompass different orientations of the device in addition to the particular orientations depicted in the figures and described herein. For example, if a structure depicted in the figures is turned over or flipped over, portions previously described as below or beneath other elements would then be above or over those other elements.

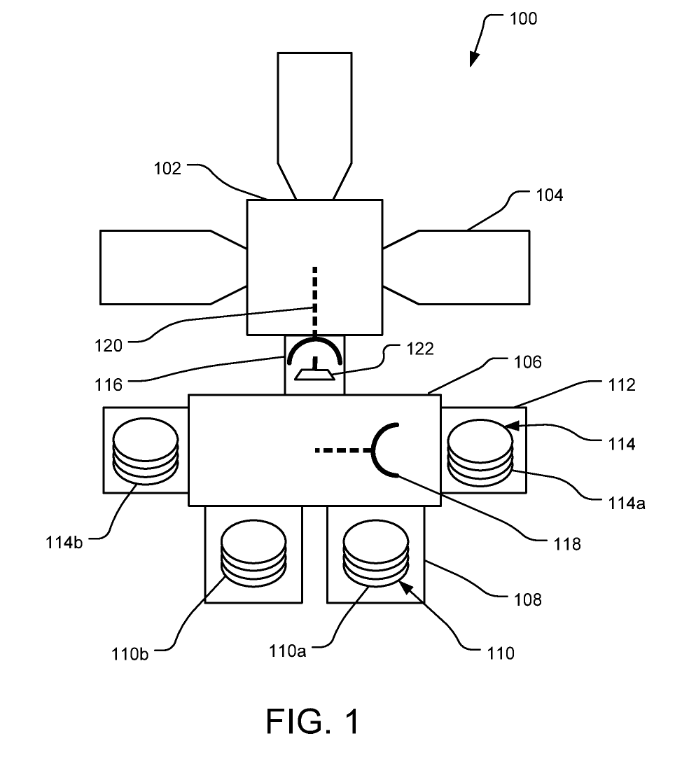

Turning to FIG. 1, a processing system 100 is illustrated having an integrated loadlock chamber 116. The system 100 includes a transfer chamber 102 operably connected to at least one process module 104. In the illustrated implementation, three process modules 104 are shown. Each process module 104 can be a module that performs, for example, CVD (chemical vapor deposition), MOCVD (metal organic CVD), ion beam deposition, chemical etching, ion milling, physical vapor deposition, DLC (diamond-like carbon) deposition, or other processing operations. The transfer chamber 102 is a sealed chamber when in use, in some implementations, under vacuum, i.e., having an internal pressure less than atmospheric pressure.

The system 100 also has an atmospheric handling station 106, which, in the illustrated implementation, includes wafer storage pods 108 for storing wafers 110 therein and carrier storage pods 112 for storing carriers 114 therein. Each of the pods 108, 112 are sized and shaped to hold a stack of the wafers 110 and the carriers 114, respectively. A wafer storage pod 108 includes a pod for storing a stack of unprocessed wafers 110a and a separate pod for receiving processed wafers 110b. Likewise, carrier storage pod 112 has a pod for storing a stack of unused carriers 114a and a separate pod for receiving used carriers 114b. Some implementations may use an external aligner at the handling station 106 for pre- and/or post-process alignment of the wafer 110 in the pods 108,

The loadlock chamber 116 connects the transfer chamber 102 with the handling station 106. The loadlock chamber 116 is a variable pressure interlock chamber, being at atmospheric pressure when open and connected to the handling station 106, and being at vacuum conditions when open and connected to the transfer chamber 102.

A robotic arm with an end effector 118 is configured to move wafers 110 from pod 108 and carriers 114 from pod 112 to loadlock chamber 116. Similarly, a robotic arm with an end effector 120 is configured to move the carrier 114 holding a wafer 110 from loadlock chamber 116 to transfer chamber 102. The end effectors 118, 120 and their appropriate robotic arms are mounted to move unhindered into and out from loadlock chamber 116. In some implementations, the end effectors 118, 120 are part of a pivoting linear robot.

The end effectors 118, 120 are shaped and sized to support one wafer 110 or one carrier 114 by their bottom surface; that is, the wafer 110 or carrier 114 rests on the end effectors 118, 120. The end effectors 118, 120 are shown as curved forks in FIG. 1, although it is understood that other configurations are suitable; for example, an end effector 118 or 120 can be a straight fork or a curved or arcuate fork, having for example, 2 or 4 tines, or one or both end effectors 118, 120 can be a paddle. Other designs for the end effectors 118, 120 include those with a vacuum suction mechanism or with an edge grip mechanism. The end effector 120 may be different from or the same as the end effector 118.

Also present within the loadlock chamber 116 is a vertically-oriented lifting head 122. The lifting head 122 engages the top surface of a wafer 110 in the loadlock chamber 116 and moves (e.g., lifts and lowers) the wafer 110 onto and off of a carrier 114. In some implementations, the vertically-oriented lifting head 122 has an auto-aligning feature, to facilitate properly aligning and/or centering the wafer 110 during movement of the wafer 110.

Based on its structure, the system 100 supports a wafer by its bottom surface using an end effector, inputs the wafer into a loadlock chamber, lifts the wafer off of the end effector using the vertically-oriented lifting head, aligns the wafer with a recess in a top surface of a carrier, and releases the wafer from the head into the recess. The system 100 also raises the wafer from the recess via the lifting head, deposits the wafer onto the end effector, and removes the wafer from the loadlock chamber.

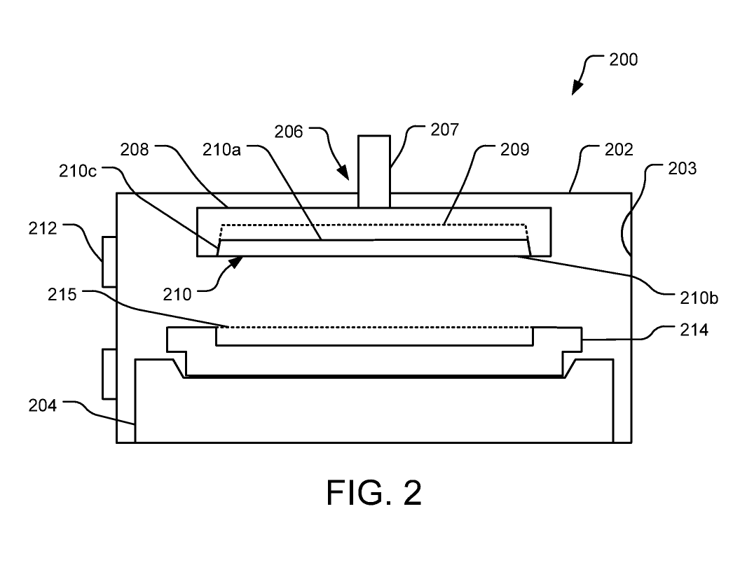

FIG. 2 shows a view of a loadlock system 200 having an interlock chamber 202 with an interior volume 203. Present within the chamber 202 is a carrier plate 204 and a vertically-oriented lifting head 206 having a shaft 207 supporting a wafer-receiving member 208 having a recess 209. The receiving member 208 is vertically adjustable in relation to the interior volume 203 of the chamber 202 via the shaft 207. In FIG. 2, a wafer 210 is shown supported in the recess 209 of receiving member 208. The wafer 210 has a top surface 210a, which will eventually be or has been processed; the top surface 210a is within the recess 209. The wafer 210 also has an opposite bottom surface 210b, which is exposed, and a side edge 210c that connects the top surface 210a and the bottom surface 210b. In the illustrated implementation, the wafer 210 has a beveled side edge 210c; other implementations may have the wafer with a straight edge or a different beveled or chamfered edge.

The receiving member 208 of the lifting head 206 supports the wafer 210 in the recess 209 by non-contact engagement with the top surface 210a, in order to inhibit contaminating the top surface 210a; the receiving member 208 may or may not contact all or a portion of the side edge 210c of the wafer 210. Either or both of the receiving member 208 or the recess 209 may have an auto-aligning feature, such as a taper or chamfer, that facilitates auto-aligning engagement of the wafer 210 into the recess 209 in the x-y orientation; the auto-aligning feature may be annular or may be present at only a portion of the receiving member 208. Examples of mechanisms to lift and hold the wafer 210 into the recess 209 include electrostatic force(s), magnetic force(s), vacuum or pressure, and pneumatic force(s). Some implementations may also make use of lift pins to engage the wafer 210.

A particular example of a suitable receiving member 208 is a Bernoulli head, sometimes called a Bernoulli wand. A Bernoulli head uses jets of gas to create a gas flow pattern above the top surface 210a of the wafer 210 that causes the pressure immediately above wafer 210 to be less than the pressure immediately below the wafer 210, at bottom surface 210b. The pressure differential causes wafer 210 to engage into the recess 209, due to the upward “lift” force or suction force formed by the Bernoulli head. The same gas jets that produce the lift force into the recess 209 produce an even larger repulsive force that prevents the top surface 210a from physically contacting the Bernoulli head. As a result, it is possible to suspend the wafer in a substantially non-contacting manner with reference to the top surface 210a. Also, in the illustrated load lock system 200, the wafer 210 cannot seat deeper into the recess 209 due to the narrowing or tapering diameter of the recess 209.

Opposite the vertically-oriented lifting head 206, present on the carrier plate 204, is a carrier 214 configured for receiving and supporting the wafer 210 during processing of the wafer 210. The carrier 214 includes a recess 215 therein for receiving the wafer 210, particularly the bottom surface 210b of the wafer 210, therein.

Also present in system 200 are sensor(s) 212, in this implementation mounted on the wall of the chamber 202. Each sensor 212 may be any suitable sensor, such as visual, laser, vibrational, etc. to monitor the system 200 for any error, such as misalignment of the wafer 210 with the lifting head 208 or the recess 209, with the recess 215 in the carrier 214, or the like.

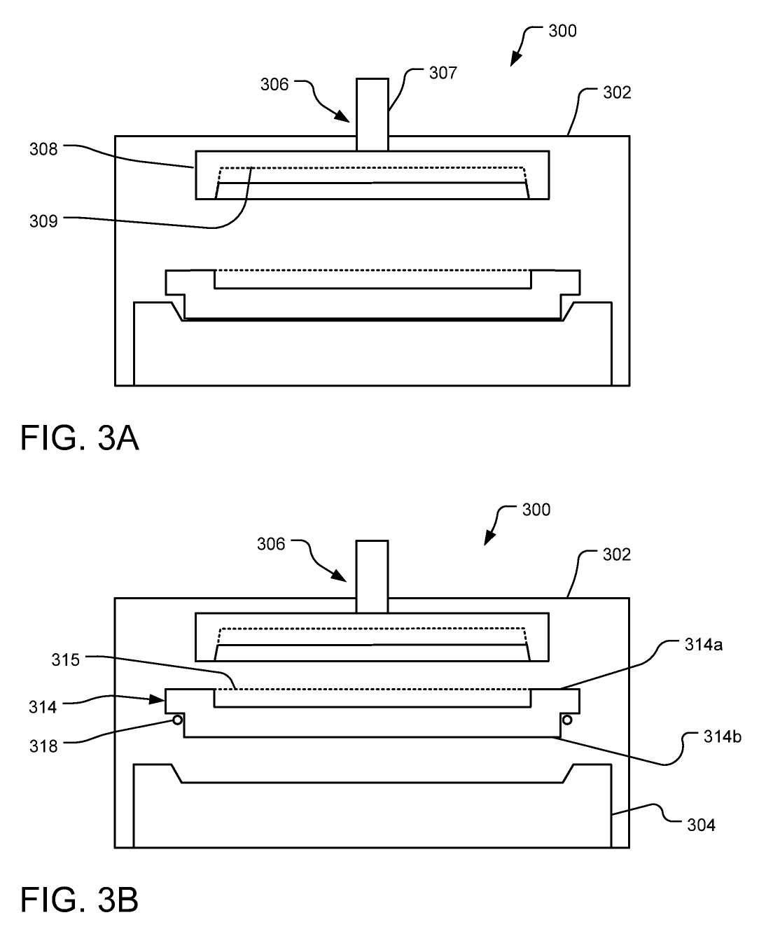

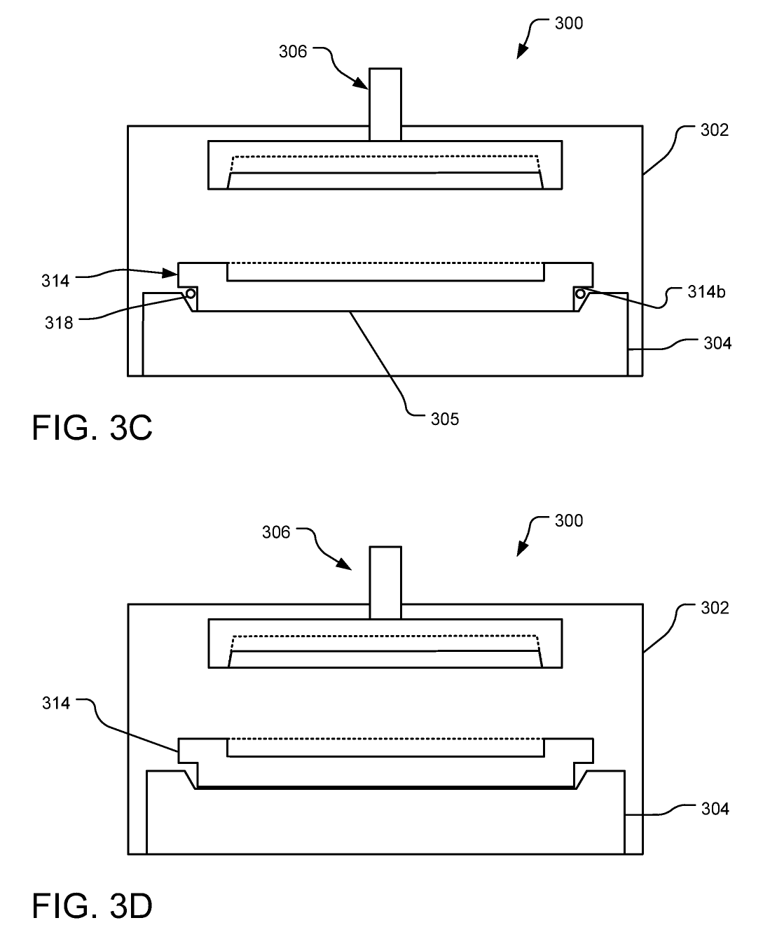

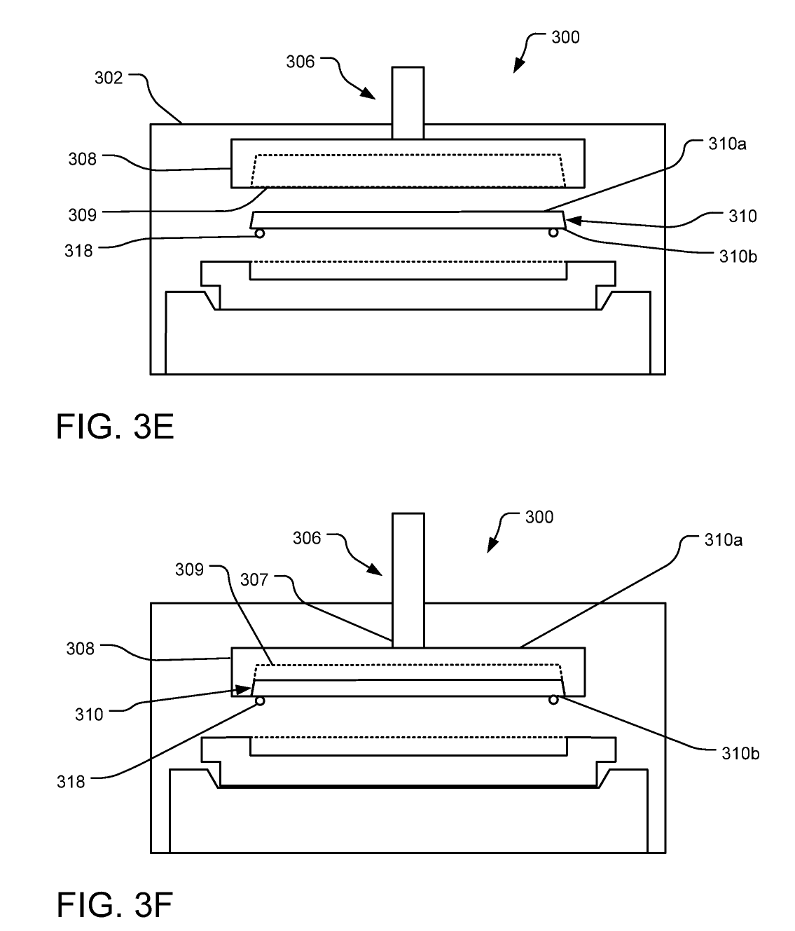

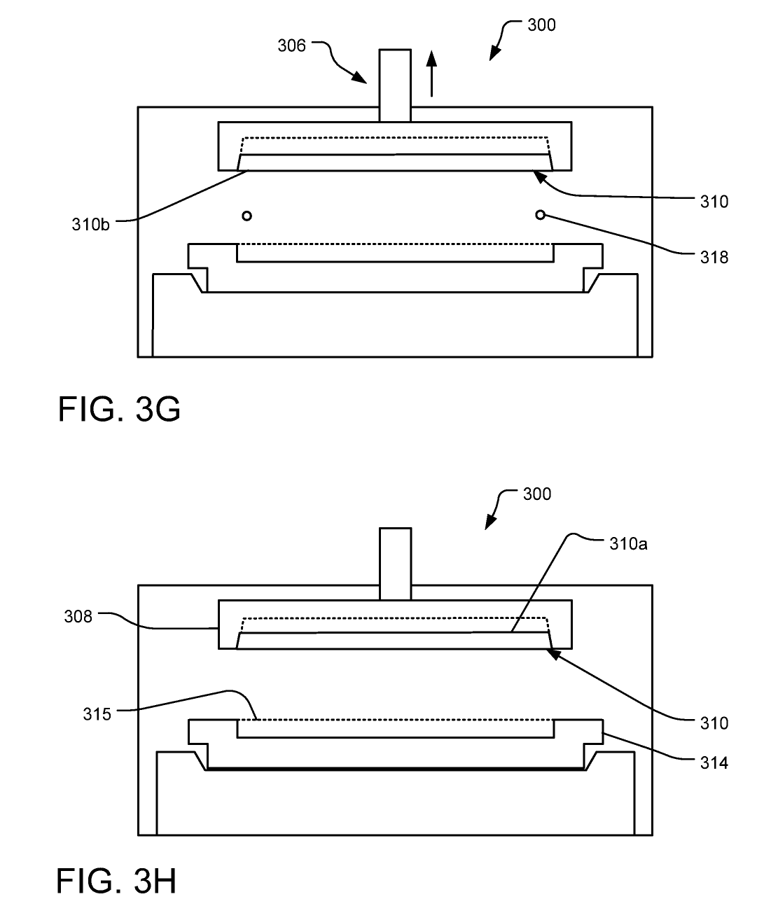

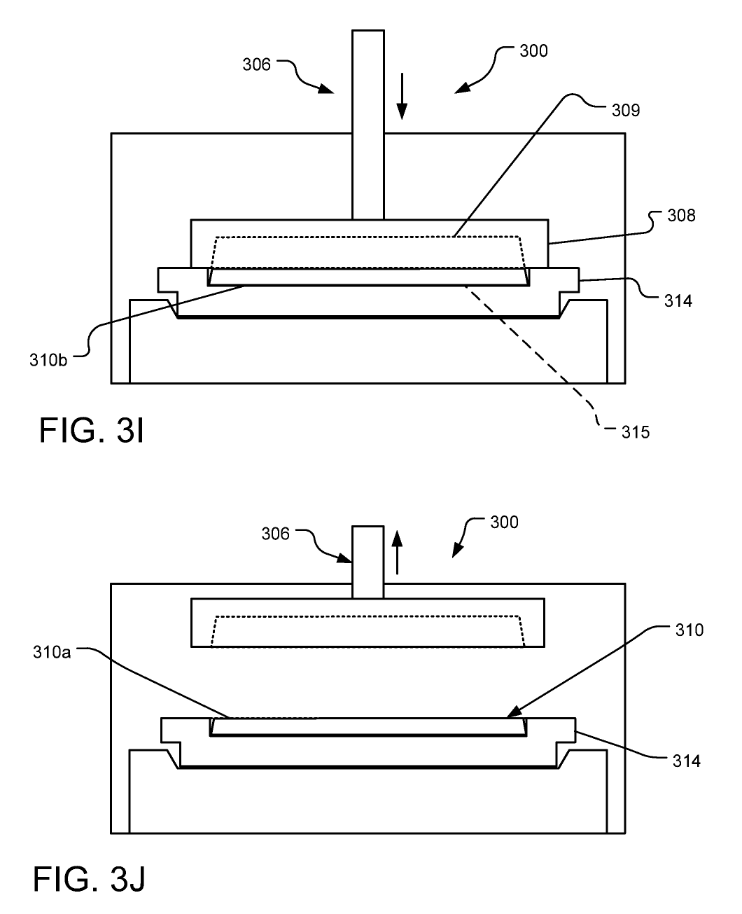

FIGS. 3A through 3J illustrate, step-wise, a method of loading a carrier and a wafer into a loadlock system 300, using an end effector, such as a robotic end effector. The end effector supports both the carrier and the wafer by their bottom surfaces during transport, avoiding physical contact with their top surfaces. Additionally, the loadlock system 300 includes a vertically-oriented lifting head that transports the wafer by its top surface in a substantially non-contacting manner relative to the top surface of the wafer.

In FIG. 3A, a loadlock system 300 is shown, system 300 having an interlock chamber 302 with a carrier plate 304 and a vertically-oriented lifting head 306 centered over the carrier plate 304. The lifting head 306 has a shaft 307 supporting a wafer-receiving member 308 having a recess 309 for receiving a wafer.

In FIG. 3B, a carrier 314 having a top surface 314a with a recess 315 therein and a bottom surface 314b is brought into the interlock chamber 302 supported on an end effector 318. The end effector 318 supports the carrier 314 by its bottom surface 314b, avoiding physical contact with its top surface 314a. This particular implementation of the carrier 314 has a feature on the bottom surface 314b characterized as a ledge, lip, tab or ear that facilitates lifting by the end effector 318, particular by a forked end effector, which can be situated with a tine on each side of the carrier 314.

In FIG. 3C, the carrier 314 is shown placed on the carrier plate 304 by the end effector 318, still shown supporting the carrier plate 304 by its bottom surface 314b. The carrier plate 304 and/or the carrier 314 may include an aligning or seating feature to facilitate proper alignment of the carrier 314 onto the carrier plate 304. In the illustrated implementation, the carrier plate 304 has a tapered recess 305 in which the carrier 314 sits. As indicated above, a forked end effector 318 is effective in gently placing the carrier 314 on the carrier plate 304 by keeping a tine on each side of the carrier plate 304. The recess 305 is sufficiently large and deep so that the end effector 318 does not hinder the seating of the carrier 314 on the carrier plate 304, and so that the end effector 318 can be readily withdrawn from under the carrier 314, as illustrated in FIG. 3D.

In FIG. 3D, the end effector 318 is shown removed from under the carrier 314, so that the carrier 314 is supported by the carrier plate 304 in the interlock chamber 302. In this figure, the end effector 318 has been removed from the interlock chamber 302 and the loadlock system 300 by its robotic arm.

FIG. 3E shows a wafer 310, having a top surface 310a and a bottom surface 310b, supported by the end effector 318 being brought into the interlock chamber 302. The wafer 310 is balanced on the end effector 318 and centered under the recess 309 of wafer-receiving member 308 by the end effector 318.

In FIG. 3F, the lifting head 306 is lowered via the shaft 307 so that the recess 309 of the wafer-receiving member 308 is brought into close proximity with the top surface 310a of the wafer 310. At this stage, the bottom surface 310b of the wafer 310 is still in contact with the end effector 318. The wafer-receiving member 308 is activated (e.g., for a Bernoulli head, the jets are activated) so that the wafer 310 is received into and supported in the recess 309 without physical contact between the wafer-receiving member 308 and the top surface 310a; any contract with the wafer 310, if at all, is with the edge of the wafer. The position of the wafer 310, with its top surface 310a in non-physical contact with the wafer-receiving member 308, may be due to the lifting mechanism of the member 308, the shape of the recess 309, or a combination of the two.

In FIG. 3G, the lifting head 306 with the wafer 310 supported thereby is raised to lift the bottom surface 310b of the wafer 310 off from the end effector 318.

In FIG. 3H, the end effector 318 is removed from the interlock chamber 302, leaving the wafer 310 suspended in the wafer-receiving member 308 above the carrier 314 and aligned with the recess 315.

In FIG. 3I, the lifting head 306 with the wafer 310 supported thereby is lowered and the wafer 310 is seated into the recess 315 of the carrier 314, particularly, the bottom surface 310b of the wafer 310 is seated into the recess 315. In some implementations, the recess 315 may be beveled or chamfered, to further facilitate centering of the wafer 310 into the recess 315. After the wafer 310 is seated, the wafer-receiving member 308 is deactivated (e.g., for a Bernoulli head, the jets are turned off) so that the wafer 310 is released from the recess 309 and dropped into the recess 315.

In FIG. 3J, the vertically-oriented lifting head 306 is raised off from the wafer 310, exposing the top surface 310a. The surface 310a of the wafer 310, aligned with and securely seated in the recess 315 of the carrier 314, is ready to be processed.

In some implementations, after the wafer 310 is securely seated on the carrier 314, the pressure within the interlock chamber 302 is reduced, creating a negative or vacuum pressure in the interlock chamber 302. When the desired pressure is obtained, a mechanism moves the combined wafer 310 and carrier 314 into a processing chamber for processing by one or more process modules. A robotic arm, e.g., with an end effector, may be used to move the wafer 310 and the carrier 314 into the processing chamber; for example, the combined wafer 310/carrier 314 can be moved by the end effector engaging the bottom surface of the carrier.

After the wafer 310 has been processed as desired, a mechanism (e.g., robotic arm, e.g., with an end effector) moves the processed wafer 310 and the carrier 314 back into the interlock chamber 302. In some implementations, the pressure within the interlock chamber 302 is returned to atmospheric, after which the processed wafer 310 and the used carrier 314 can be removed or unloaded from the interlock chamber 302.

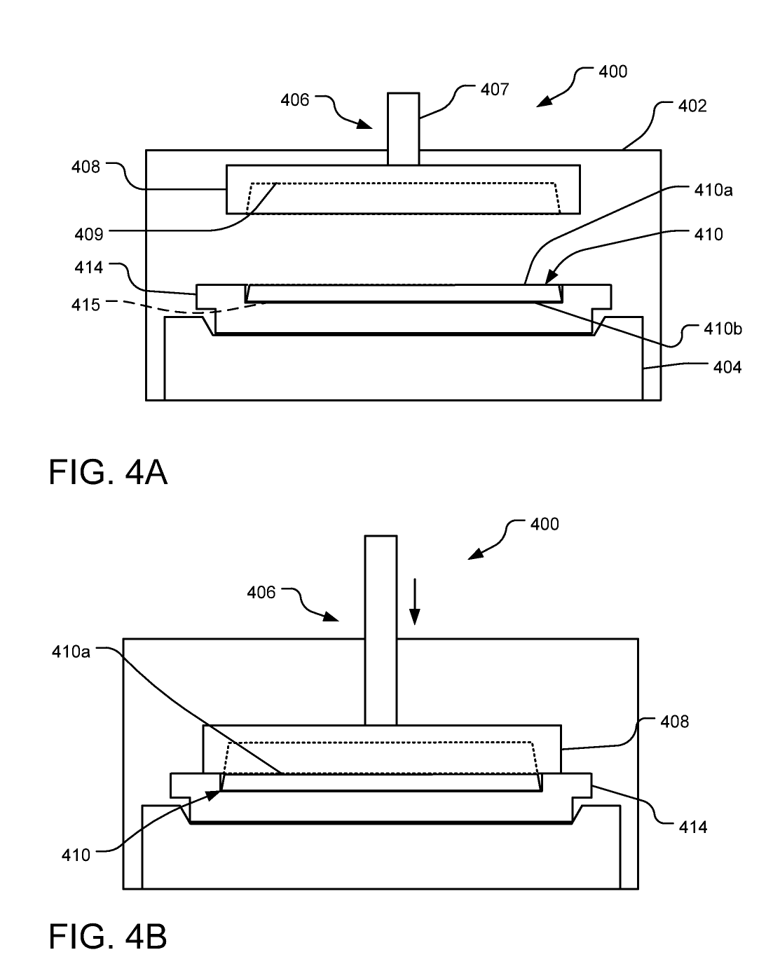

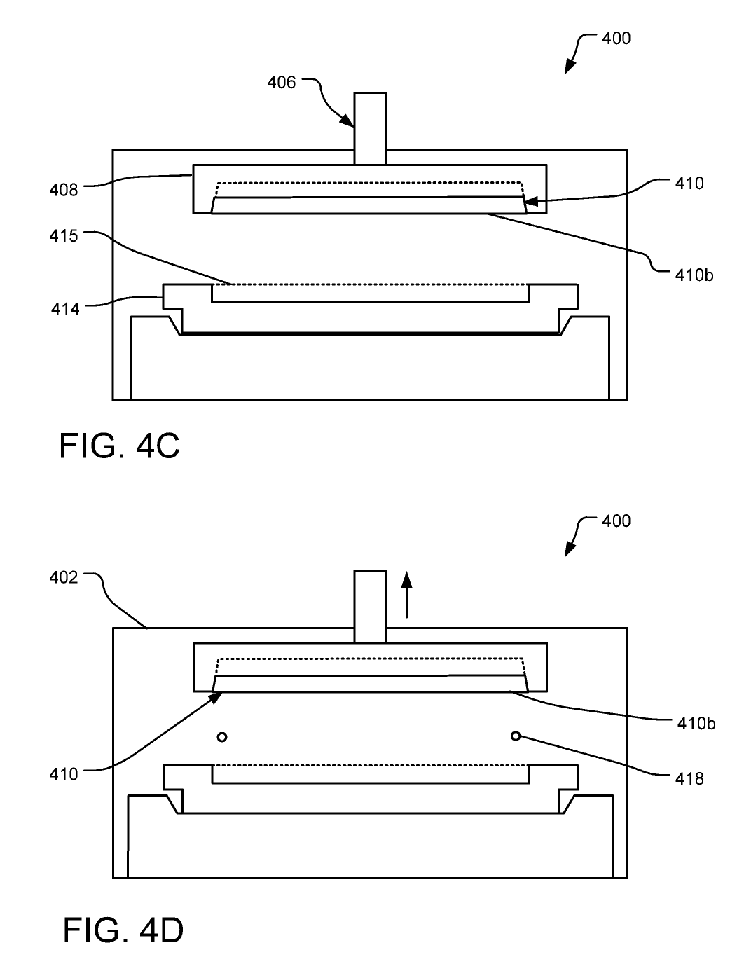

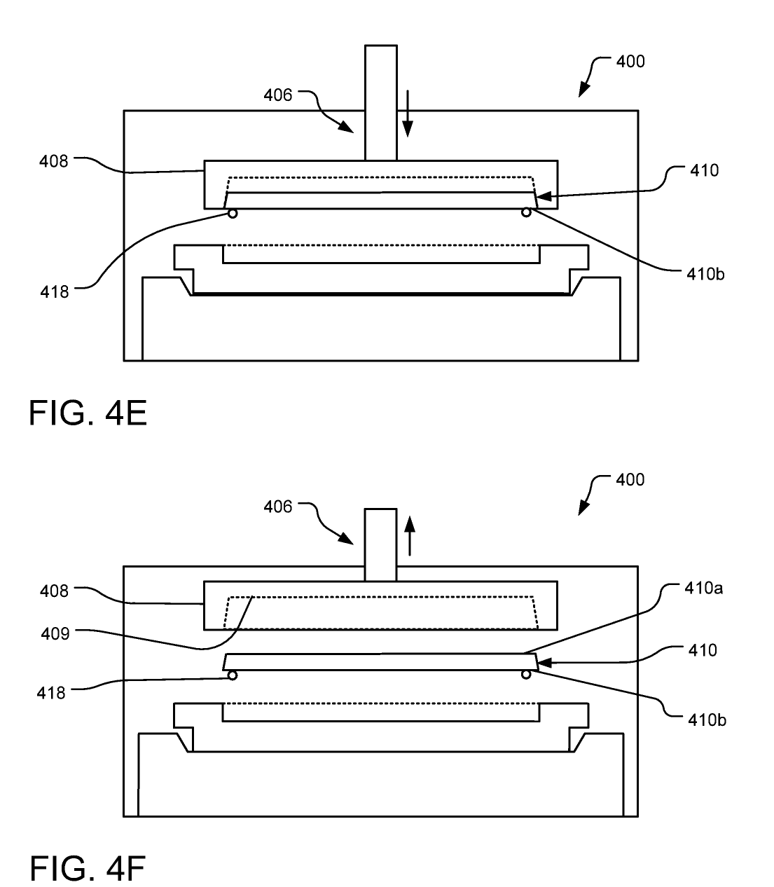

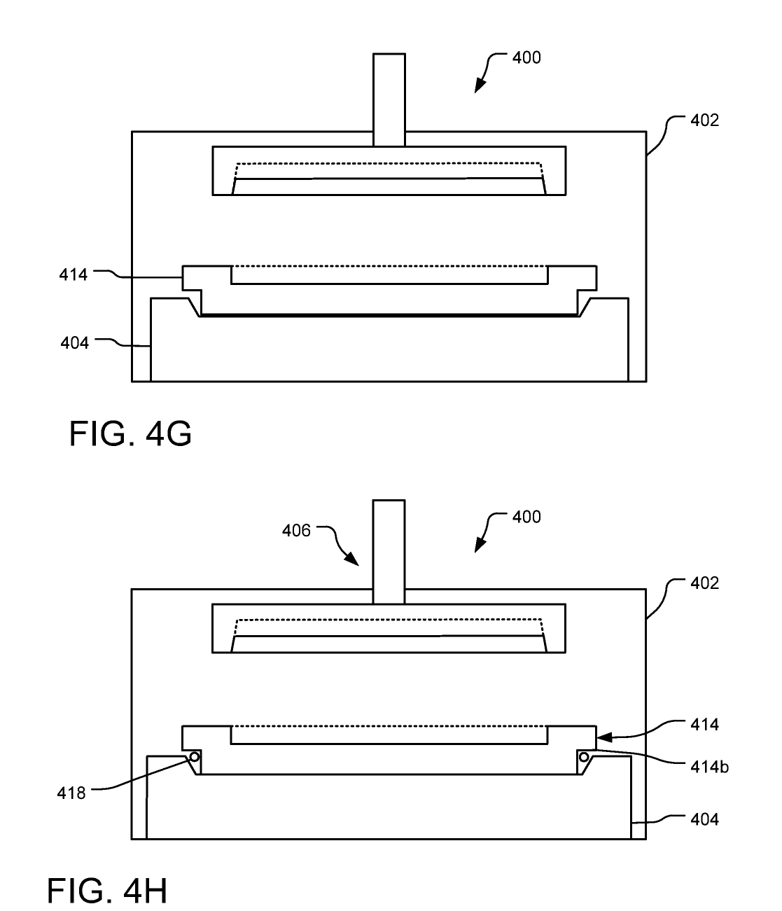

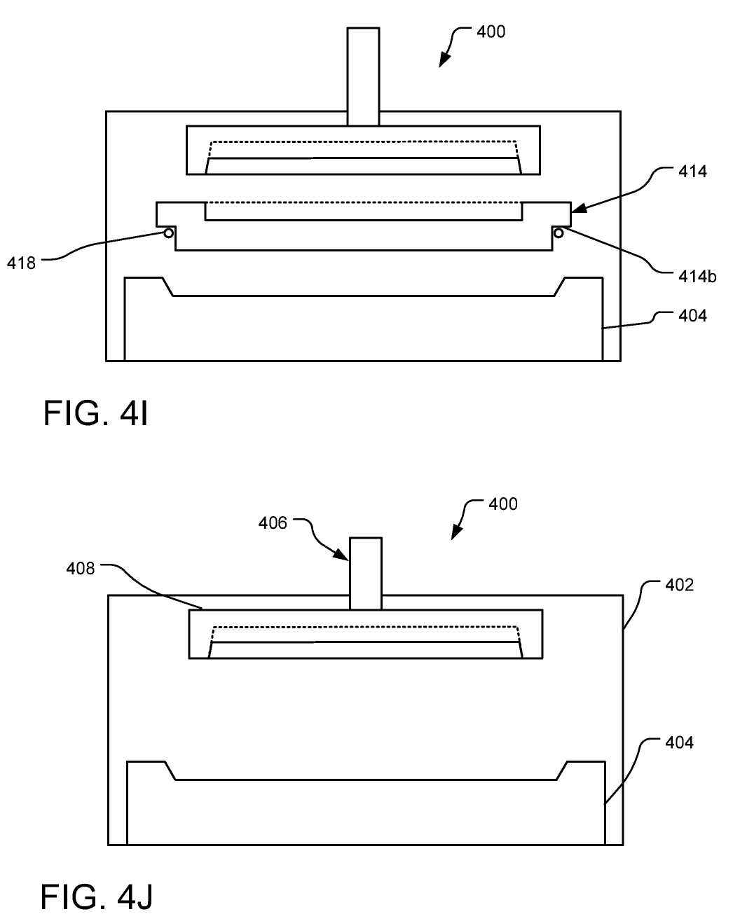

FIGS. 4A through 4J illustrate, step-wise, a method of unloading a wafer and a carrier from a loadlock system 400 using a forked end effector. Similar to the loading process shown in FIGS. 3A through 3J, during the unloading process the end effector supports both the carrier and the wafer by their bottom surfaces, avoiding physical contact with their top surfaces. Also similar to the process shown in FIGS. 3A through 3J, the loadlock system 400 includes a vertically-oriented lifting head that transports the wafer by its top surface in a substantially non-contacting manner relative to the top surface of the wafer.

In FIG. 4A, a loadlock system 400 is shown, having an interlock chamber 402 with a carrier plate 404 and a vertically-oriented lifting head 406 therein, the lifting head 406 having a shaft 407 supporting a wafer-receiving member 408 having a recess 409 for receiving a wafer. Positioned on the carrier plate 404 is a carrier 414 with a recess 415. A wafer 410 (e.g., a processed wafer), having a top surface 410a and a bottom surface 410b, is present in the recess 415 in the carrier 414.

In FIG. 4B, the lifting head 406 is lowered over the wafer 410 on the carrier 414. The wafer-receiving member 408 (e.g., a Bernoulli head) is activated, to engage and hold the top surface 410a of the wafer 410 in a substantially non-contacting manner.

In FIG. 4C, the lifting head 406 is raised, thus lifting wafer 410 and its bottom surface 410b out of the recess 415 in the carrier 414. Once out of the recess 415, the wafer 410 is suspended by the wafer-receiving member 408, in some implementations, in a non-physical contact manner with the top surface 410a.

In FIG. 4D, an end effector 418 is brought into the interlock chamber 402 below the bottom surface 410b of the raised wafer 410. In this implementation, the end effector 418 is the same end effector used during a wafer loading process.

In FIG. 4E, the lifting head 406 with the wafer 410 held by the wafer-receiving member 408 is lowered so that the bottom surface 410b of the wafer 410 contacts and sits upon the end effector 418.

In FIG. 4F, the wafer-receiving member 408 is deactivated or turned off, allowing the wafer 410 to be released from the recess 409 and thus supported on its bottom surface 410b by the end effector 418. The lifting head 406 is raised off of the wafer 410, exposing the top surface 410a.

In FIG. 4G, the end effector 418 and the wafer 410 supported thereon are removed from the system 400, leaving the carrier 414 on the carrier plate 404 in the interlock chamber 402.

In FIG. 4H, the end effector 418 is shown returned to the chamber 402 and positioned around the carrier plate 404 and under the carrier 414. The end effector 418 contacts the bottom surface 414b of the carrier 414.

In FIG. 4I, the carrier 414 is lifted off from the carrier plate 404 by the end effector 418 contacting the bottom surface 414b, and in FIG. 4J, the interlock chamber 402 is shown with the carrier 414 and the end effector 418 removed therefrom. The carrier plate 404 and the vertically-oriented lifting head 406, particularly the wafer-receiving member 408, remain in the chamber 402.

The previous figures, FIGS. 3A through 3J have shown an exemplary, step-wise method of moving and engaging a wafer and a carrier using a robotic end effector and a vertically-oriented lifting head. FIGS. 4A through 4J have shown an exemplary, step-wise method of moving and separating a processed wafer from its carrier using a robotic end effect and a, vertically-oriented lifting head. The end effector moves both the wafer and the carrier via their bottom, non-working surfaces. The lifting head moves the wafer in a non-contacting manner with the wafer's top surface.

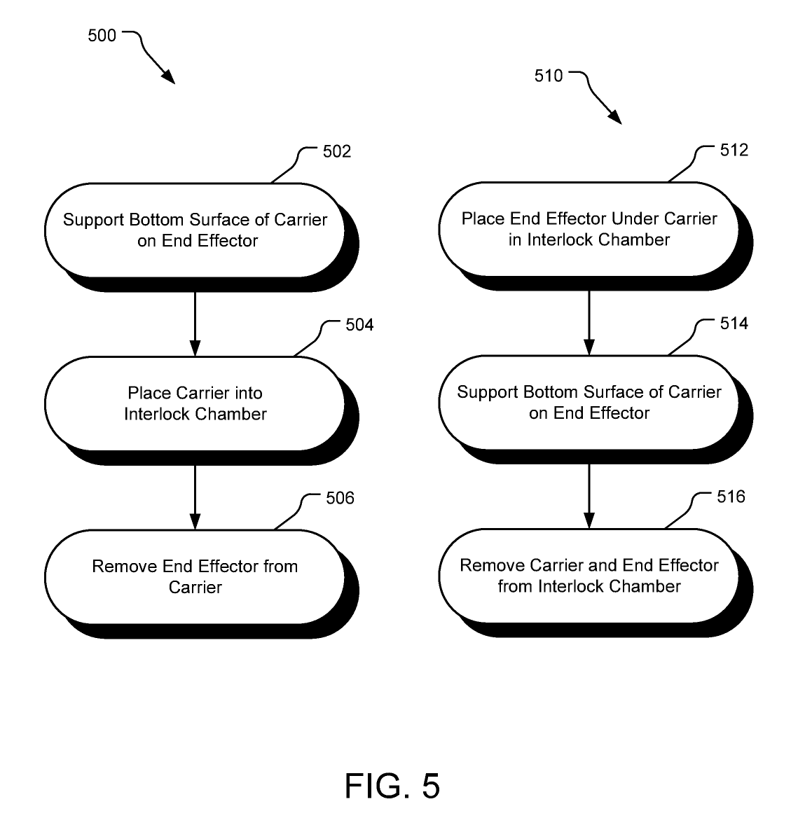

FIG. 5 shows a flow diagram of two example methods for moving a carrier in relation to an interlock chamber of a loadlock system using an end effector.

In the first method, method 500, the carrier is supported by its bottom surface by an end effector in operation 502. In operation 504, the end effector places the carrier into the interlock chamber. In operation 506, the end effector is removed form the carrier, leaving the plate in the interlock chamber.

In the second method, method 510, in operation, the end effector is placed under the carrier while in the interlock chamber. In operation 514, the carrier is supported via its bottom surface by the end effector. The carrier and end effector are removed from the interlock chamber in operation 516.

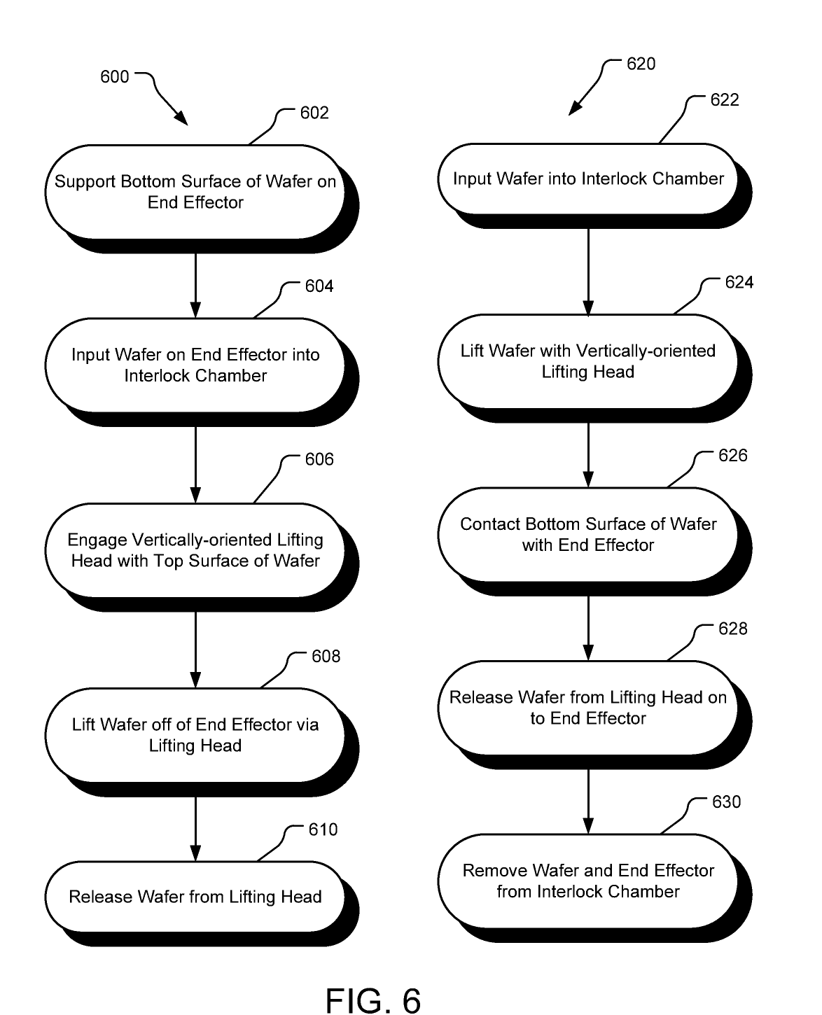

FIG. 6 shows a flow diagram of two example methods for moving a wafer in relation to an interlock chamber of a loadlock system using an end effector and a vertically-oriented lifting head.

The first method, method 600, includes operation 602, where the wafer is supported by its bottom surface by the end effector. In operation 604, the thus supported wafer is inputted into the interlock chamber of a loadlock system. In operation 606, the vertically-oriented lifting head is engaged with the top surface of the wafer, and the wafer is lifted off from the end effector by the lifting head in operation 608. In operation 610, the wafer is released from the lifting head.

In the second method, method 620, the wafer is provided into the interlock chamber in operation 622. In operation 624, in the interlock chamber, the wafer is lifted with the vertically-oriented lifting head. In operation 626, the bottom surface of the lifted wafer is contacted with the end effector. In operation 628, the wafer is released form the lifting head on to the end effector. In operation 630, the wafer, supported by the end effector, is removed from the interlock chamber.

The above specification and examples provide a complete description of the structure, features and use of exemplary embodiments of the invention. Since many embodiments of the invention can be made without departing from the spirit and scope of the invention, the invention resides in the claims hereinafter appended. Furthermore, structural features of the different embodiments may be combined in yet another embodiment without departing from the recited claims.

What is claimed is:

1. A system comprising:
a chamber having an interior;
a carrier plate within the chamber interior, the carrier plate configured to receive a carrier;
a vertically-oriented lifting head vertically moveable within the chamber;
a first end effector moveable into and out from the chamber vertically between the carrier plate and the head;
a second effector moveable into and out from the chamber vertically between the carrier plate and the head; and
at least one sensor operably connected to the chamber interior.

2. The system of claim 1, wherein the chamber is an interlock chamber.

3. The system of claim 1, wherein the first end effector is forked.

4. The system of claim 1, wherein the second end effector is forked.

5. The system of claim 1, wherein the vertically-oriented lifting head is an auto-aligning, vertically-oriented lifting head comprising a chamfered edge.

6. The system of claim 5, wherein the auto-aligning, vertically-oriented lifting head is a Bernoulli head.

7. The system of claim 1, wherein the vertically-oriented lifting head comprises lift pins.

8. A method of processing a wafer, comprising:
aligning a wafer with a recess in a top surface of a carrier in an interlock chamber using a vertically-oriented lifting head; and
placing the wafer in the recess with the lifting head.

9. The method of claim 8 further comprising, prior to aligning the wafer:
lifting the wafer off of an end effector in the interlock chamber with the auto-aligning, vertically-oriented lifting head.

10. The method of claim 9 further comprising, prior to lifting the wafer off of an end effector:
placing the wafer in the interlock chamber with the end effector.

11. The method of claim 8 further comprising, prior to aligning the wafer:
placing the carrier in the interlock chamber with an end effector.

12. The method of claim 8, wherein the vertically-oriented lifting head has an electrostatic, magnetic, vacuum, or pneumatic mechanism.

13. The method of claim 8, wherein the vertically-oriented lifting head is a Bernoulli head.

14. The method of claim 8, wherein the end effector is forked.

15. A method of processing a wafer, comprising:
supporting a wafer by its bottom surface on an end effector;
inputting the wafer into an interlock chamber;
lifting the wafer off the end effector in the interlock chamber using a vertically-oriented lifting head;
aligning the wafer with a recess in a top surface of a carrier in the interlock chamber; and
releasing the wafer from the head into the recess.

16. The method of claim 15 further comprising:
lifting the wafer from the recess with the head in the interlock chamber; and
placing the bottom surface of the wafer on the end effector.

17. The method of claim 15, wherein the vertically-oriented lifting head has an electrostatic, magnetic, vacuum, or pneumatic mechanism.

18. The method of claim 15, wherein the vertically-oriented lifting head has a chamfered portion.

19. The method of claim 15, wherein the vertically-oriented lifting head is a Bernoulli head.

20. The method of claim 15 further comprising, prior to aligning the wafer with the recess in the carrier,
supporting the carrier with an end effector; and
inputting the carrier into the interlock chamber.

21. The method of claim 20, wherein the end effector that supports the carrier is a different end effector than that supports the wafer.

22. The method of claim 15, wherein lifting the wafer off the end effector comprises non-contactingly lifting the wafer by its top surface.
